(19) United States
(12) Patent Application Publication
(10) Pub. No.: US 2024/0243712 A1
(43) Pub. Date: Jul. 18, 2024

(54) MOS DIFFERENTIAL PAIR

(71) Applicant: STMicroelectronics (Alps) SAS, Grenoble (FR)

(72) Inventors: Vratislav MICHAL, Fontanil-Cornillon (FR); Samuel FOULON, ISERE (FR)

(73) Assignee: STMicroelectronics (Alps) SAS, Grenoble (FR)

(21) Appl. No.: 18/411,748

(22) Filed: Jan. 12, 2024

(30) Foreign Application Priority Data
Jan. 16, 2023 (FR) 2300400

(51) Int. Cl. H03F 3/45; H03F 1/32

(52) U.S. Cl. CPC H03F 3/45183; H03F 1/3205; H03F 3/45744

(57) ABSTRACT

A differential pair circuit includes a first branch and a second branch having a common first node. Each of the first and second branches includes at least one transistor having a conduction node directly connected to the common first node. A third branch couples the common first node to a power supply node. The third branch includes a current source in series with a resistive element.

### PRIORITY CLAIM

This application claims the priority benefit of French Application for Patent No. 2300400, filed on Jan. 16, 2023, the content of which is hereby incorporated by reference in its entirety to the maximum extent allowable by law.

### TECHNICAL FIELD

The present disclosure relates generally to electronic circuits and, in particular, to differential pairs of transistors and more particularly MOS differential pairs in operational amplifiers.

### BACKGROUND

Numerous analog functions such as operational amplifiers using MOS transistors comprise an entry (or input) stage with a differential pair (called MOS differential pair). The accuracy of the existing MOS differential pairs is affected by high frequency electromagnetic fields.

There is a need to provide a MOS differential pair circuit which is less sensitive to high frequency electromagnetic fields.

### SUMMARY

One embodiment addresses all or some of the drawbacks of known transistor differential pairs.

One embodiment provides a differential pair comprising: a first and a second branches having a common first node, each branch comprising at least one transistor having a conduction node directly connected to said common first node; a third branch coupling said common first node to a power supply node, and comprising a current source in series with a resistive element. The circuit further includes a capacitor having a first terminal coupled to a gate of the at least one transistor of the second branch and a second terminal coupled to ground.

According to an embodiment, said resistive element has a resistance value greater than 100 Ohms.

According to an embodiment, said resistive element has a resistance value greater than 1 kOhms.

According to an embodiment, the resistive element is a resistor.

According to an embodiment, the resistive element is a MOS transistor.

According to an embodiment, the current source is a MOS transistor.

According to an embodiment: a first conduction node of the transistor of the current source is connected to the power supply node; and a second conduction node of the transistor of the current source is coupled, by said resistive element to the first node.

According to an embodiment: a conduction node of the transistor of the current source is connected to the common first node; and another conduction node of the transistor of the current source is coupled, by said resistive element to the power supply node.

According to an embodiment, the power supply node is configured to be coupled to ground.

According to an embodiment, the current source is an NMOS transistor.

According to an embodiment, the power supply node is configured to be coupled to voltage supply rail.

According to an embodiment, the current source is a PMOS transistor.

According to an embodiment, the transistor of each of the first and second branches has its source connected to the common first node.

According to an embodiment, the transistor of each of the first and second branches is a PMOS transistor.

According to an embodiment, the transistor of each of the first and second branches is an NMOS transistor and has its drain connected to the common first node.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an example of a usual PMOS differential pair;

FIG. 2 represents a PMOS differential pair according to an embodiment;

FIG. 3 represents a PMOS differential pair according to another embodiment;

FIG. 4 details a PMOS differential pair according to an embodiment;

FIG. 5 details a NMOS differential pair according to an embodiment;

FIG. 6 illustrates the operation of a MOS differential pair according to the disclosed embodiments; and

FIG. 7 represents a differential pair according to another embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

The embodiments of the present disclosure will be described in relation with an implementation based on MOS transistors. It should however be noted that the disclosure more generally applies to other kind of differential pairs of transistors, for example bipolar (PNP or NPN), JFET, etc.

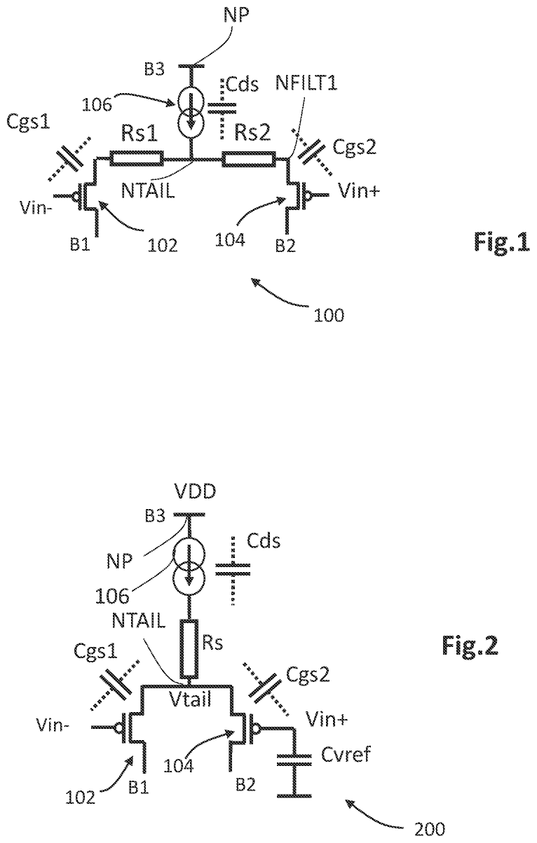

FIG. 1 represents an example of a usual MOS differential pair 100.

The MOS differential pair comprises a first branch B1 and a second branch B2. Each of the first and the second branches comprises a transistor respectively 102 and 104. In the example of FIG. 1, transistors 102 and 104 are PMOS transistors.

The source of transistor 102 is connected to a common node NTAIL by a resistor Rs1. The gate of transistor 102 defines a first input of the differential pair, for receiving a first voltage Vin− of a differential input signal. The drain of transistor 102 defines a first output of the differential pair.

The source of transistor 104 is coupled to the first node NTAIL by a resistor Rs2. The gate of transistor 104 defines a second input of the differential pair, for receiving a second voltage Vin+ of the differential input signal. The drain of transistor 104 defines a second output of the differential pair.

The MOS differential pair also comprises a third branch B3 coupling node NTAIL to a power supply node NP via a current source 106.

The circuit of FIG. 1 is commonly called a differential pair with gain degenerative resistors as the presence of resistors Rs1 and Rs2 degrades the gain of the differential pair.

In dynamic mode or when operating at high frequencies (typically radiofrequencies), gate-source parasitic capacitances (Cgs1 and Cgs2 illustrated in dotted lines) are not negligible. Furthermore, the current source 106, which is generally made of a MOS transistor, is, at high frequencies, equivalent to its parasitic drain-source capacitance Cds. The capacitance Cds corresponds to the overall capacitance between the drain and source.

In numerous applications of a differential pair, one input, for example the gate of transistor 104, receives a reference signal and the other input (the gate of transistor 102) receives a feedback signal. In such a case, the reference signal is decoupled to ground via a stabilizing capacitance Cvref of the reference signal (see, FIG. 2).

The RF equivalent circuit is therefore unbalanced as the RF filtering due to the resistors Rs1 and Rs2 and the capacitances are not perfectly equal on both branches. An offset current at the output of the differential pair may moreover result from the inherent nonlinearity of the MOS transistor in saturation regime.

The same will apply in the absence of degenerative resistors as the unbalanced capacitances in the branches remains except that the effect will be stronger as the difference between parasitic RF Vgs voltages of transistors 102 and 104 is higher.

More generally, the current structures of differential pairs are not adapted to high frequencies operation without providing additional RC filters at the inputs and output of the differential pair.

The disclosed embodiments provide an alternative solution avoiding the need of RC filtering at input/output of the differential pair or at least reducing the size of the components of such RC filtering cells.

FIG. 2 illustrates a MOS differential pair 200 according to an embodiment.

The MOS differential pair 200 is similar to the MOS differential pair 100 of FIG. 1 except that in first and second branches B1, B2, the resistances Rs1 and Rs2 are absent and the sources of the transistors 102 and 104, respectively, are connected directly to node NTAIL. Moreover, compared to the example of FIG. 1, the third branch B3 comprises an additional resistive element Rs in series with the current source. In the example represented, the current source 106 is coupled to node NTAIL by the resistive element Rs and is coupled, preferably connected, to a node NP of application of a power voltage, for example a voltage supply rail VDD.

The resistive element Rs is an additional element to the circuit, i.e., does not result from a parasitic resistance such as resulting from the circuit layout or interconnects. The resistive element Rs is implemented for example by a polysilicon, a metal or other types of resistors or by a MOS transistor for example a PMOS transistor. If the resistor is made of a MOS transistor, the drain-source resistance will be chosen high enough to render negligible the impact of the overlap capacitance (drain-source capacitance). The resistance of the resistive element Rs is greater than 100 Ohms, preferably greater than 1 kOhms, for example few tens of kOhms.

An advantage of the circuit as represented in FIG. 2 is that there is no gain degradation as the resistive element Rs is in the third branch, i.e., the branch common to both differential transistors.

Furthermore, in RF frequencies, the operation of both branches is symmetrical as the equivalent filtered point is node NTAIL. This ensures an efficient filtering of an RF voltage VTAIL at node NTAIL with a time constant depending on the value of the resistive element Rs and on the equivalent capacitance connected to NTAIL, e.g., ((Cgs2*Cvref)/(Cgs2+Cvref)) as in the example of FIG. 2. Additionally, a substrate capacitance to the ground also contributes to the filtering of the RF voltage at Vtail node. Therefore, an offset due to radiofrequency parasitic signals on node NP on the output signals is reduced on both branches B1 and B2.

An architecture as showed in FIG. 2 is therefore particularly adapted to high frequency high accuracy operational amplifiers for reducing RF-induced offset, and also partly improving power supply rejection ratio (PSRR).

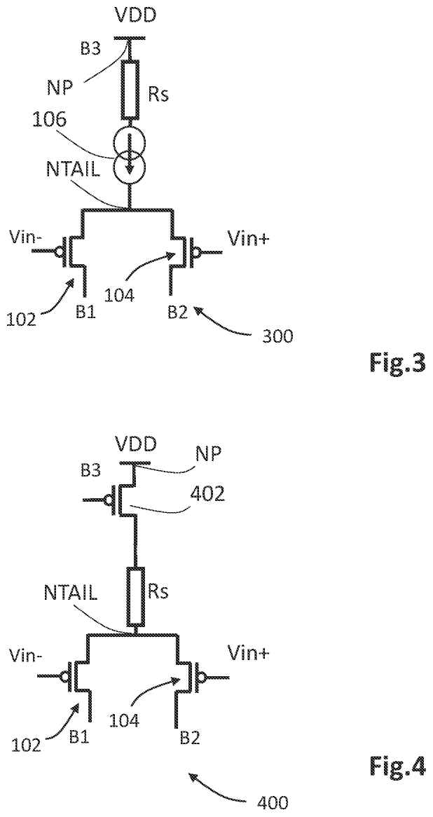

FIG. 3 illustrates a MOS differential pair 300 according to another embodiment.

The differential pair 300 is similar to the differential pair 200 of FIG. 2 except that the current source 106 and the resistive element Rs are inverted in the third branch B3. In other words, the resistive element Rs of the third branch is coupling the power supply node NP to the current source, coupled, preferably connected, to the node NTAIL. To simplify the representation of FIG. 3, the capacitance Cvref is not shown but is present as in FIG. 2.

The operation of the circuit of FIG. 3 is similar to the one of FIG. 2.

FIG. 4 details a MOS differential pair 400 according to an embodiment.

The architecture of the differential pair 400 is similar to the one of differential pair 200 of FIG. 2. FIG. 4 shows an embodiment of current source 106, which is implemented by a PMOS transistor 402. The drain of transistor 402 is coupled, preferably connected, to the supply voltage node NP and its source is coupled, preferably connected, to the resistive element Rs.

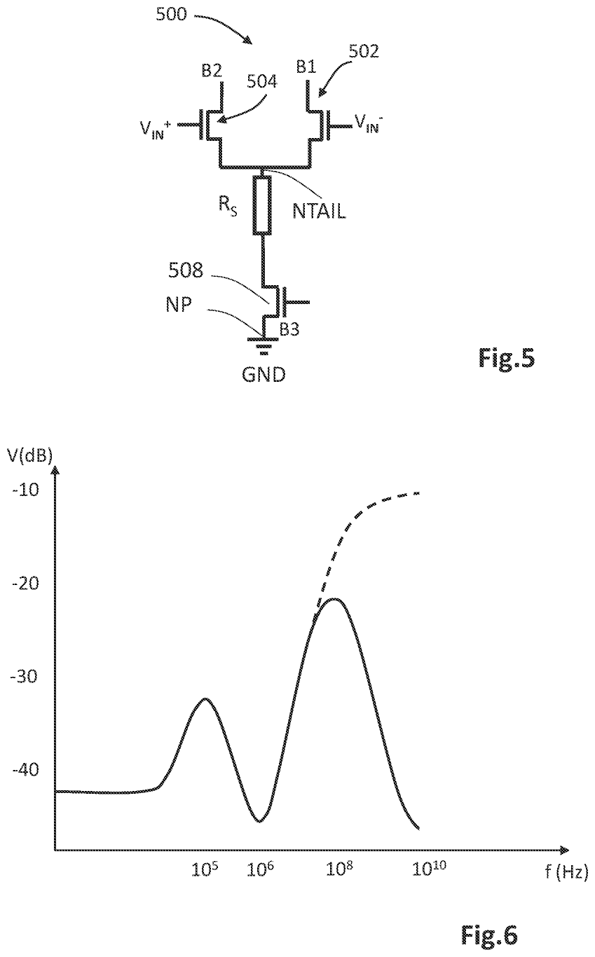

FIG. 5 details a MOS differential pair 500 according to an embodiment.

The architecture of the differential pair 500 is similar to the one of differential pair 400 of FIG. 4 except that transistors are NMOS transistors. The current source 106 is implemented by a transistor 508 having its source coupled, preferably connected, to the supply voltage node NP and its drain coupled, preferably connected, to the resistive element Rs. The supply voltage node NP is configured to be coupled, or preferably connected, to ground GND and the transistors of the first and second branches are NMOS transistors 502 and 504. The transistors 502, 504 have their respective drain coupled, preferably connected, to the node NTAIL.

FIG. 6 illustrates the operation of a MOS differential pair according to the disclosed embodiments.

More precisely, FIG. 6 represents an example of the voltage attenuation of the transfer function Vtail/VNP (VNP being the voltage at node NP) as function of the frequency with a comparison of the examples of FIG. 1 and FIG. 2. In FIG. 6, the behavior of the differential pair 100 is represented with a dashed line, and the behavior of the differential pair 400 is represented with a solid line. In the case of the differential pair 400, the Rs value of the differential pair of FIG. 4 is assumed to be 10 kOhms.

At frequencies lower than around 30 MHz the differential pairs 100 and 400 behave approximatively similarly.

For frequencies over 30 MHz, the attenuation difference is increasing between the differential pair 400 and the differential pair 100. For example, at about 700 MHz, the attenuation is about −23 dB for the differential pair 400 and about −18 dB for the differential pair 100. At about 3 GHz, the attenuation is about −40 dB for the differential pair 400 and about −10 dB for the differential pair 100. The noise of RF perturbations at the powering node NP is thus considerably reduced with the embodiments as disclosed.

Another advantage of the disclosed embodiments is that their implementation adds very limited additional thermal and flicker noise to the differential pair, contrary to the case of the degrading resistors RS1, RS2 from FIG. 1. This is thanks to the fact that RF filtering resistance Rs is connected in series with the current source 106.

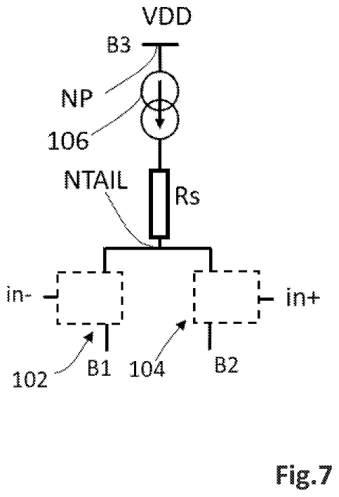

FIG. 7 represents a differential pair according to another embodiment. The example of FIG. 7 is similar to the example of FIG. 2 except that, in the example of FIG. 7, transistors 102 and 104 are replaced by other types of transistors such as bipolar transistors, PNP, NPN, JFET or others. The current source 106 is, for example, implemented by a transistor of the same type as the transistors 102 and 104.

In this case, the transistors 102 and 104 are respectively supplied with inputs in− and in+, which can be voltage or current supplies depending on the type of transistors implemented.

Various embodiments and variants have been described. Those skilled in the art will understand that certain features of these embodiments can be combined and other variants will readily occur to those skilled in the art. In particular, the resistive element Rs and the transistor 508 of FIG. 5 could be inverted such as in the example of FIG. 3. Similarly, the resistive element Rs and the transistor 402 of FIG. 5 could be inverted such as in the example of FIG. 3.

Finally, the practical implementation of the embodiments and variants described herein is within the capabilities of those skilled in the art based on the functional description provided hereinabove. In particular, even if the detailed embodiments of FIGS. 2 to 5 mention MOS transistors, one with an ordinary skill in the art could envisage all types of transistors e.g., bipolar transistors, PNP, NPN, JFET or other types such as described in FIG. 7.

1. A differential pair, comprising:
a first and a second branches having a common first node, each of the first and second branches comprising at least one transistor having a conduction node directly connected to said common first node;
a third branch coupling said common first node to a power supply node;
wherein said third branch comprises a current source in series with a resistive element; and
a capacitor having a first terminal coupled to a gate of the at least one transistor of the second branch and a second terminal coupled to ground.

2. The differential pair of claim 1, wherein said resistive element has a resistance value greater than 100 Ohms.

3. The differential pair of claim 1, wherein said resistive element has a resistance value greater than 1 kOhms.

4. The differential pair of claim 1, wherein the resistive element is a resistor.

5. The differential pair of claim 1, wherein the resistive element is a MOS transistor.

6. The differential pair of claim 1, wherein the current source is a MOS transistor.

7. The differential pair of claim 6, wherein:
a first conduction node of the transistor of the current source is connected to the power supply node; and
a second conduction node of the transistor of the current source is coupled, by said resistive element to the common first node.

8. The differential pair of claim 6, wherein:
a conduction node of the transistor of the current source is connected to the common first node; and
another conduction node of the transistor of the current source is coupled by said resistive element to the power supply node.

9. The differential pair of claim 1, wherein the power supply node is configured to be coupled to ground.

10. The differential pair of claim 9, wherein the current source is an NMOS transistor.

11. The differential pair of claim 1, wherein the power supply node is configured to be coupled to voltage supply rail.

12. The differential pair of claim 11, wherein the current source is a PMOS transistor.

13. The differential pair of claim 11, wherein the transistor of each of the first and second branches has its source connected to the common first node.

14. The differential pair of claim 11, wherein the transistor of each of the first and second branches is a PMOS transistor.

15. The differential pair of claim 1, wherein the transistor of each of the first and second branches is an NMOS transistor and has its drain connected to the first node.
